(19) United States
(12) Patent Application Publication
(10) Pub. No.: US 2005/0150544 A1
(43) Pub. Date: Jul. 14, 2005

(54) Dye-sensitized solar cell

(75) Inventors: Atsushi Fukui, Kashiba-shi (JP); Ryohsuke Yamanaka, Gojyo-shi (JP); Ryoichi Komiya, Kashiba-shi (JP); Liyuan Han, Kilakatsuragi-gun (JP)

Correspondence Address: NIXON & VANDERHYE, PC, 1100 N GLEBE ROAD, 8TH FLOOR, ARLINGTON, VA, 22201-4714, US

(73) Assignee: Sharp Kabushiki Kaisha, Osaka (JP)

(21) Appl. No.: 11/000,949

(22) Filed: Dec. 2, 2004

(30) Foreign Application Priority Data
Dec. 5, 2003 (JP) 2003-407899
Dec. 5, 2003 (JP) 2003-407908
Dec. 5, 2003 (JP) 2003-407916

(51) Int. Cl. H01L 31/00

(52) U.S. Cl. 136/263

(57) ABSTRACT

The present invention provides a dye-sensitized solar cell including: a transparent electrode; a counter electrode; a porous semiconductor layer having a dye sensitizer adsorbed therein; and a carrier transport layer containing an electrolytic solution therein, the porous semiconductor layer and the carrier transport layer being located between the transparent electrode and the counter electrode, wherein the electrolytic solution contains a heterocyclic compound comprising a heteroatom in the ring.

### CROSS-REFERENCES TO RELATED APPLICATIONS

This application is related to Japanese applications Nos. 2003-407899, 2003-407908 and 2003-407916 filed on Dec. 5, 2003 whose priorities are claimed under 35 USC 119, the disclosures of which are incorporated by reference in their entirety.

### BACKGROUND OF THE INVENTION

1. Field of the Invention

The present invention relates to a dye-sensitized solar cell and, more particularly, to a dye-sensitized solar cell with a high conversion efficiency that has a carrier transport layer containing an electrolytic solution.

2. Description of Related Art

Conventionally, as a device for directly converting light energy to electric energy, crystalline silicon solar cells have been well known and have been utilized in the field of weak power consumption, and as an independent power source and also as a power source for use in aerospace. Crystalline silicon solar cells are made mainly of a silicon single crystal or amorphous silicon. Producing a silicon single crystal and amorphous silicon, however, requires enormous amounts of energy and, in order to recover energy consumed for manufacturing cells, electric power generation needs to be carried out continuously for nearly a ten-year long period.

Under these circumstances, dye-sensitized solar cells utilizing a dye sensitizer have attracted wide attention. Dye-sensitized solar cells include, for example, a transparent conductive film; a porous semiconductor electrode (hereafter, also referred to as a semiconductor electrode) having a dye sensitizer supported therein; a carrier transport layer; and a counter electrode formed in this order on a transparent substrate. Dye-sensitized solar cells have been expected to serve as a solar cell for the next generation because of simplicity and convenience of fabrication methods thereof, reduced material costs therefore and the like.

In J. Am Ceram. Soc., 80(12) 3157-3171(1997), it describes a method of manufacturing a dye-sensitized solar cell in which a dye sensitizer such as a transition metal complex is adsorbed on the surface of a titanium oxide electrode that is a porous semiconductor. In this method, a dye-sensitized solar cell is manufactured as follows: a transparent substrate on which a transparent conductive film and a semiconductor electrode of titanium oxide are formed is immersed in a solution containing a dye sensitizer so that the dye sensitizer is supported in the semiconductor electrode; an electrolytic solution containing a redox compound is applied dropwise onto the semiconductor electrode; and a counter electrode is stacked on the resulting semiconductor electrode.

In the solar cell thus obtained, upon irradiation of the semiconductor electrode with visible light, the dye sensitizer supported in the semiconductor electrode absorbs the light so that an electron in the dye sensitizer is excited, and the excited electron is inject into the semiconductor electrode, is brought into the transparent electrode and then moves through an electric circuit to the counter electrode. The electron then moves to a carrier transport layer and is brought by a hole or an ion through the carrier transport layer and returns to the semiconductor electrode. Electric energy is generated by repetition of this process.

However, in order for dye-sensitized solar cells to be put in practical use, there has been a demand for a further improvement in conversion efficiency, and for that, there has been a demand for an increase in the current to be generated (short-circuit current), in open-circuit voltage and also in durability.

In order to increase the open-circuit voltage, it is necessary to decrease a reverse current passing from the semiconductor electrode to the dye sensitizer and/or to the carrier transport layer. In an equivalent circuit in a silicon solar cell, the correlation between a reverse current I₀ and an open-circuit voltage V_{oc} is expressed by the following equation (1):

$${V}_{oc} = \frac{nkT}{q} ln ( \frac{{I}_{ph}}{{I}_{0}} ) \qquad equation ( 1 )$$

wherein, Iₚₕ is the photocurrent; n is the diode factor; k is the Boltzmann constant; T is the absolute temperature; and q is the charge number of a carrier.

In a dye-sensitized solar cell, although the equation (1) does not necessarily hold stringently, it is considered that, as is the case with a silicon solar cell, the open-circuit voltage V_{oc} decreases resulting from an increase in reverse current. It is known that, for example, as proposed in J. Am Ceram. Soc., 80(12) 3157-3171(1997), adding tert-butylpyridine (TBP) to an electrolytic solution or treating a dye-adsorbed electrode with a solution containing TBP are effective in suppressing the reverse current in the dye-sensitized solar cell.

When TBP is used, however, a marked decrease in short-circuit current is observed, and the actually obtained open-circuit voltage is low when compared with a theoretically expected open-circuit voltage.

Japanese Unexamined Patent Publication No. 2003-168494 proposes a technique of using a metal complex dye as a dye sensitizer and adding, to an electrolytic solution, a compound having the same chemical species as that of a ligand of the metal complex dye. This technique is intended to suppress elution of the ligand of the metal complex dye into an electrolytic solution and exchange thereof with an electrolyte contained in the electrolytic solution so as to improve the durability of a solar cell.

Specific examples of compounds include ketones, nitrites, alcohols, pyridines, carboxylic acids, dimethylformamide, dimethyl sulfoxide, hexamethylphosphoramide, tetrahydrofuran, water and the like. The concentration of the compound in the electrolyte is 50 to 99% by weight.

With the compound contained in the above concentration, however, an imidazole salt, which is generally used as an additive for an electrolytic solution, has a low solubility. Also, the addition of the compound will lead to an increase in the viscosity of a solvent in the electrolytic solution, which results in a marked decrease in short-circuit current and in fill factor and thus a noticeable decrease in conversion efficiency. Especially, when tetrahydrofuran, a highly volatile substance, is contained in a high concentration in the electrolytic solution, the durability of the solar cell might possibly be greatly reduced.

### SUMMARY OF THE INVENTION

The inventor of the present invention eagerly studied dye-sensitized solar cells while taking the above problems into account and found that, when the electrolytic solution contains a particular heterocyclic compound, it is possible to provide a dye-sensitized solar cell with a high open-circuit voltage, a high photoelectric conversion efficiency and a suppressed reverse current. Thus, the present invention is achieved.

The present invention provides a dye-sensitized solar cell comprising: a transparent electrode; a counter electrode; a porous semiconductor layer having a dye sensitizer adsorbed therein; and a carrier transport layer containing an electrolytic solution therein, the porous semiconductor layer and the carrier transport layer being located between the transparent electrode and the counter electrode, wherein the electrolytic solution contains a heterocyclic compound comprising a heteroatom in the ring.

Also, the present invention provides a dye-sensitized solar cell comprising: a transparent electrode; a counter electrode; a porous semiconductor layer having a dye sensitizer adsorbed therein; and a carrier transport layer containing an electrolytic solution therein, the porous semiconductor layer and the carrier transport layer being located between the transparent electrode and the counter electrode, wherein the electrolytic solution contains a heterocyclic compound containing an oxygen atom in the ring, and the concentration of the heterocyclic compound in the electrolytic solution is 5 to 40% by volume.

Further, the present invention provides a dye-sensitized solar cell comprising: a transparent electrode; a counter electrode; a porous semiconductor layer having a dye sensitizer adsorbed therein; and a carrier transport layer containing an electrolytic solution therein, the porous semiconductor layer and the carrier transport layer being located between the transparent electrode and the counter electrode, wherein the electrolytic solution contains a heterocyclic compound containing two or more oxygen atoms in the ring.

Still further, the present invention provides a dye-sensitized solar cell comprising: a transparent electrode; a counter electrode; a porous semiconductor layer having a dye sensitizer adsorbed therein; and a carrier transport layer containing an electrolytic solution therein, the porous semiconductor layer and the carrier transport layer being located between the transparent electrode and the counter electrode, wherein the electrolytic solution contains a heterocyclic compound containing at least one sulfur atom in the ring.

These and other objects of the present application will become more readily apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed de scrip tion.

### BRIEF DESCRIPTION OF THE DRAWINGS

FIG. 1 is a schematic diagram showing a dye-sensitized solar cell according to the present invention.

### DESCRIPTION OF THE PREFERRED EMBODIMENTS

A dye-sensitized solar cell according to the present invention includes at least a porous semiconductor layer having a dye sensitizer adsorbed (or supported) therein and a carrier transport layer containing an electrolytic solution between a transparent electrode and a counter electrode. Typically, the transparent electrode and the counter electrode are formed on supporting substrates, respectively. The supporting substrate having the transparent electrode formed thereon is transparent.

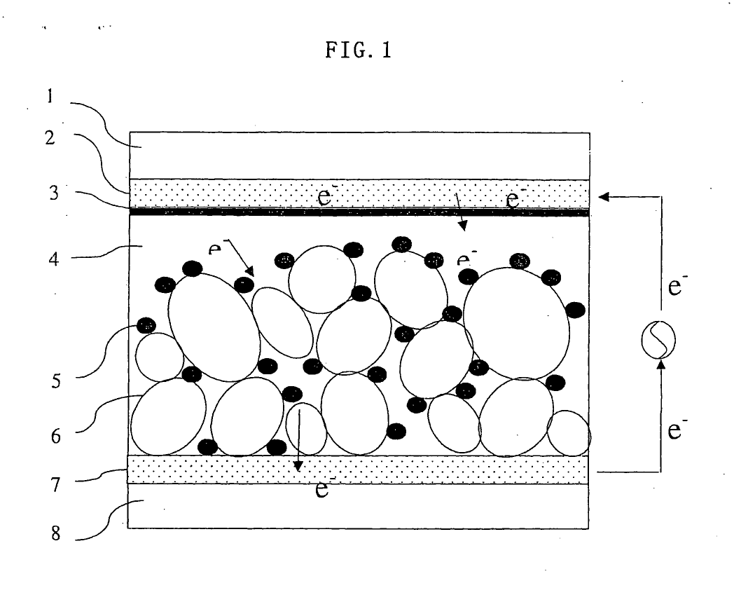

FIG. 1 is a schematic cross section of an exemplary dye-sensitized solar cell according to the present invention.

Supporting substrates 1 and 8 may be glass substrates, plastic substrates or the like, and the thicknesses thereof are not particularly limited as long as they permit the solar cell to have an appropriate strength. At least one of the supporting substrates 1 and 8 is transparent.

Transparent conductive films 2 and 7 are formed on the supporting substrates 1 and 8, respectively. Examples of materials for the transparent conductive films include transparent conductive materials such as ITO, F-doped SnO₂, SnO₂, CuI, ZnO and the like. The transparent conductive films are formed by a conventional method (for example, a sol-gel method, a sputtering method or the like), and the thicknesses thereof are suitably about 0.1 to 5 μm. The transparent conductive film 2, which, in FIG. 1, is formed on a counter electrode 3, may be omitted.

The porous semiconductor layer 6 is formed on the transparent conductive film 7 and made of semiconductor minute particles. The semiconductor minute particles may be any as long as they are generally used for photoelectric conversion materials. Examples of semiconductor minute particles include minute particles of substances such as titanium oxide, zinc oxide, tin oxide, niobium oxide, zirconium oxide, cerium oxide, tungsten oxide, silicon oxide, aluminum oxide, nickel oxide, barium titanate, strontium titanate, cadmium sulfide, CuAlO₂, SrCu₂O₂ and the like. These substances may be used alone or in combination.

Among the above-mentioned examples of semiconductor minute particles, preferable are titanium oxide particles in terms of stability and safety. Examples of titanium oxides include various kinds of strictly defined titanium oxides such as anatase type titanium oxide, rutile type titanium oxide, amorphous titanium oxide, metatitanic acid and orthotitanic acid, as well as titanium hydroxide and hydrated titanium oxide. The semiconductor layer may be in the form of particles or a film, but preferably it is in the form of a porous film or the like.

The porous semiconductor layer may be formed on the transparent conductive film by any of various known methods. More specifically, the following methods and their combinations may be exemplified:
(1) a method of forming the porous semiconductor layer on the transparent conductive film by applying a suspension containing semiconductor minute particles to a transparent conductive film, and drying and/or calcining the suspension;
(2) a method of forming the porous semiconductor layer on the transparent conductive film by a CVD method or a MOCVD method using a necessary material gas; and
(3) a method of forming the porous semiconductor layer by a PVD method using a solid as a raw material, a deposition method, a sputtering method or a sol-gel method.

The semiconductor minute particles used for forming the porous semiconductor layer preferably have an average particle diameter within the range of, for example, 1 to 400 nm. Here, the average minute particle diameter is determined by analyzing dynamic scattering of laser light with use of a light scattering photometer (manufactured by Ohtsuka Denshi Ltd., Japan). The semiconductor minute particles may be commercially available ones.

For example, in the method (1), first, the semiconductor minute particles are added to an appropriate solvent to prepare a suspension. Examples of solvents include Glyme type solvents such as ethylene glycol monomethyl ether; alcohols such as isopropyl alcohol; alcohol type mixed solvents such as isopropyl alcohol/toluene; and water. Next, the suspension containing the semiconductor minute particles is applied to the transparent conductive film by a known method such as a doctor blade method, a squeeze method, a spin coating method or a screen printing method. After that, the coating solution is dried and calcined to obtain the porous semiconductor layer.

In the above method, the temperature, duration, atmosphere and the like at the time of drying and calcination may properly be adjusted depending on the types of the transparent conductive layer and semiconductor particles to be employed. For example, the drying and calcination may be carried out at a temperature of about 50 to 800° C. for about 10 seconds to 12 hours in atmospheric air or an inert gas atmosphere. The drying and calcination may be carried out only once at a constant temperature or two or more times at varying temperatures.

The application, drying and calcination may be carried out only once or more times.

In the method (2), the material gas to be used may be a single gas or a mixture of two or more gases containing an element forming the porous semiconductor layer.

In the method (3), the solid to be used as a raw material may be a single solid substance, combinations of a plurality of solid substances, or a solid of a compound containing an element forming the porous semiconductor layer.

The thickness of the porous semiconductor layer is not particularly limited, and it may be, for example, about 0.1 to 100 μm. The porous semiconductor layer preferably has a large surface area of, for example, about 10 to 200 m²/g.

A dye sensitizer 5 is adsorbed in the porous semiconductor layer 6. The dye sensitizer may be a dye sensitizer having absorbance in a wide range of a visible light region and/or an IR region and, for example, organic dyes and metal complex dyes may be mentioned.

Examples of organic dyes include azo type dyes, quinone type dyes, quinone-imine type dyes, quinacridone type dyes, squarylium type dyes, cyanine type dyes, merocyanine type dyes, triphenylmethane type dyes, xanthene type dyes, porphyrin type dyes, perylene type dyes, indigo type dyes and naphthalocyanine type dyes. Preferable examples of metal complex dyes include phthalocyanine type dyes and ruthenium type dyes, containing, as a dominant metal, a metal such as Cu, Ni, Fe, Co, V, Sn, Si, Ti, Ge, Cr, Zn, Ru, Mg, Al, Pb, Mn, In, Mo, Y, Zr, Nb, Sb, La, W, Pt, Ta, Ir, Pd, Os, Ga, Tb, Eu, Rb, Bi, Se, As, Sc, Ag, Cd, Hf, Re, Au, Ac, Tc, Te, Rh or the like.

According to the present invention, in order for the dye sensitizer to be firmly adsorbed in the porous semiconductor layer, it is preferable to use dye sensitizers having in a molecule thereof an interlocking group such as a carboxyl group, an alkoxy group, a hydroxyl group, a sulfonic acid group, an ester group, a mercapto group or a phosphonyl group.

Among the above-mentioned dye sensitizers, preferable are ruthenium type dyes, and particularly preferable are Ruthenium 535 dye expressed by the following general formula (1), Ruthenium 535-bisTBA dye expressed by the following general formula (2) and Ruthenium 620-1H3TBA dye expressed by the following general formula (3).

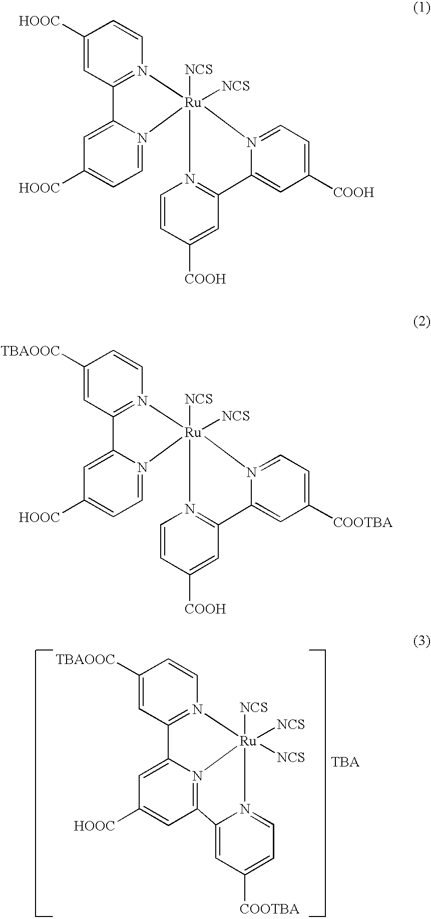

Before the dye sensitizer 5 is adsorbed in the porous semiconductor layer 6, a treatment for activating the surface of the porous semiconductor layer may be carried out upon necessity. The adsorption of the dye sensitizer in the porous semiconductor layer may be carried out by immersing the porous semiconductor layer in a liquid containing the dye sensitizer. The liquid may be any as long as the dye sensitizer can be dissolved therein, and specific examples of liquids include organic solvents such as alcohol, toluene, acetonitrile, chloroform and dimethylformamide. Typically, these solvents are preferably purified ones. The concentration of the dye sensitizer in the solvent may properly be adjusted depending on the types of the dye and solvent to be used and also on the conditions of the step of adsorbing the dye sensitizer, and it is preferably 1×10⁻⁵ mol/l or higher.

In the immersion of the porous semiconductor layer in the liquid containing the dye sensitizer, the temperature, pressure and duration may be varied upon necessity. The immersion may be carried out only once or a plurality of times and, after the immersion, the drying may be carried out properly.

The dye sensitizer adsorbed in the porous semiconductor layer by the method functions as a photosensitizer that sends electrons to the porous semiconductor layer upon receipt of light energy. In general, in the case where the dye sensitizer has an interlocking group, the dye sensitizer is fixed to the porous semiconductor layer via the interlocking group. The interlocking group provides an electric bond for facilitating the electron transportation between the dye sensitizer in the excited state and the conduction band of the porous semiconductor layer.

The counter electrode 3 may be formed either on the supporting substrate or on the transparent conductive film 2 formed on the supporting substrate. The conductive film may be transparent or opaque, and may be made of an n-type and p-type element semiconductor (e.g., silicon or germanium); an n-type and p-type compound semiconductor (e.g., GaAs, InP, ZnSe or CsS); a metal such as gold, platinum, silver, copper or aluminum; a refractory metal such as titanium, tantalum or tungsten; or a transparent conductive material such as ITO, F-doped SnO₂, SnO₂, CuI or ZnO. The counter electrode may be formed by a conventional method, and suitably has a thickness of about 0.1 to 5 μm.

The supporting substrate and the protective layer may be transparent or opaque ones that are typically used for solar cells. More specifically, the counter electrode 3 may be of a platinum film formed by a method such as sputtering, thermal decomposition of chloroplatinic acid or electrodeposition on the transparent conductive film that covers the supporting substrate. The thickness of the platinum film is preferably about 1 to 1000 nm.

A carrier transport layer 4 may be any as long as it contains an electrolytic solution and allows transportation of electrons, holes, or ions therethrough. Examples of electrolytes contained in the electrolytic solution include ion conductors such as a liquid electrolyte and an electrolytic polymer. The ion conductor is preferably redox ion conductor. The electrolyte is not particularly limited as long as it is generally usable for batteries, solar cells and the like. Specific examples of electrolytes include combinations of iodine with metal iodides such as LiI, NaI, KI (and CaI₂, and combinations of bormine with metal bromides such as LiBr, NaBr, KBr and CaBr₂, among which preferable is a combination of LiI and iodine.

The concentration of the electrolyte is suitably 0.01 to 1.5 mol/l, and preferably 0.1 to 0.7 mol/l.

Examples of solvents for the electrolyte include carbonate compounds such as propylene carbonate; nitrile compounds such as acetonitrile; alcohols such as ethanol; water; and non-protonic polar substances, among which preferable are carbonate compounds and nitrile compounds.

According to the present invention, the electrolytic solution preferably contains, as an additive, at least one of the following heterocyclic compounds (A) to (C) having a heteroatom in rings thereof.

Heterocyclic compound (A) having one oxygen atom in the ring thereof.

The heterocyclic compound (A) preferably has a five- or six-membered ring.

The heterocyclic compound (A) more preferably has a five- or six-membered ring containing one oxygen atom in the ring.

Specific examples of heterocyclic compounds (A) include furan, tetrahydrofuran, pyran, tetrahydropyran and the like, each optionally substituted with a lower alkyl group. Examples of lower alkyl groups include methyl, ethyl, n-propyl, i-propyl, n-butyl, i-butyl, sec-butyl and the like.

A single heterocyclic compound (A) or a combination of two or more heterocyclic compounds (A) may be used. For example, a combination of two heterocyclic compounds (A) such as a combination of furan and one of tetrahydrofuran, pyran and tetrahydropyran, a combination of tetrahydrofuran and one of pyran and tetrahydropyran, a combination of pyran and tetrahydropyan, or the like combination may be used. Heterocyclic compound (B) having two or more oxygen atoms in the ring thereof.

The heterocyclic compound (B) preferably has a five- or six-membered ring. The heterocyclic compound (B) more preferably has a five- or six-membered ring containing two or three heteroatoms in the ring.

Also, the heterocyclic compound is preferably selected from the group consisting of a compound having a five-membered ring containing two oxygen atoms in the ring, a compound having a six-membered ring containing two oxygen atoms in the ring, and a compound having a six-membered ring containing three oxygen atoms in the ring.

Specific examples of heterocyclic compounds (B) include dioxolane, dioxane, dioxole, dioxene, dioxin, trioxane and the like, each optionally substituted with a lower alkyl group. Examples of lower alkyl groups include methyl, ethyl, n-propyl, i-propyl, n-butyl, i-butyl, sec-butyl and the like.

A single heterocyclic compound (B) or a combination of two or more heterocyclic compounds (B) may be used. For example, a combination of two heterocyclic compounds (B) such as a combination of dioxolane and one of dioxane, dioxole, dioxene, dioxin and trioxane, a combination of dioxane and one of dioxole, dioxene, dioxin and trioxane, a combination of dioxole and one of dioxene, dioxin and trioxane, a combination of dioxene and one of dioxin and trioxane, a combination of dioxin and trioxane, or the like combination may be used.

When compared with a heterocyclic compound having one oxygen atom, a heterocyclic compound having two or more oxygen atoms generally has a high boiling point. Accordingly, addition of it even in a large amount to the electrolytic solution can suppress degradation in stability and long-term reliability of a solar cell.

Heterocyclic compound (C) having at least one sulfur atom in the ring thereof.

The heterocyclic compound (C) preferably has a five- or six-membered ring. The heterocyclic compound (C) more preferably has a five- or six-membered ring containing one to three (more particularly, one or two) sulfur atoms in the ring.

Also, the heterocyclic compound (C) preferably has a five-membered ring containing one sulfur atom in the ring.

Specific examples of heterocyclic compounds (C) include thiophene, tetrahydrothiophene and the like, each optionally substituted with a lower alkyl group. Examples of lower alkyl groups include methyl, ethyl, n-propyl, i-propyl, n-butyl, i-butyl, sec-butyl and the like.

The heterocyclic compounds (A) to (C) may be used alone or in combination.

According to the present invention, the heterocyclic compound allows an improvement in the current to be generated (shirt-circuit current) and in open-circuit voltage. The following is a conceivable reason: When a heterocyclic compound has an oxygen atom and/or a sulfur atom in the ring thereof, the oxygen atom and/or the sulfur atom in a molecule are adsorbed on sites of the porous semiconductor layer and/or dye sensitizer from which sites electrons leak, so that the leakage of the electron (reverse current) can be suppressed.

An oxygen atom and/or a sulfur atom has a large number of unshared electron pairs when compared with a nitrogen atom. For this reason, it is considered that the heterocyclic compound has a stronger ability to be adsorbed in the porous semiconductor layer and/or dye sensitizer than conventional nitrogen-containing compounds such as TBP, and thus has an improved ability to suppress the reverse current.

More particularly, it is considered that, like the rings of a nitrogen-containing heterocyclic compound, an imdazol salt and the like, the ring of the heterocyclic compound of the present invention functions (1) to reduce the size of a molecule of the heterocyclic compound, when compared with the size of a straight chain molecule having the same number of atoms, and to reduce the degree of intermolecular freedom, so as to make the molecule of the heterocyclic compound of the present invention more mobile in the porous semiconductor layer, and (2) to improve the stability of the heterocyclic compound of the present invention.

The concentration of the heterocyclic compound in the entire electrolytic solution is preferably 5 to 80% by volume and more preferably 10 to 50% by volume in consideration of a low solubility of an imidazole salt in the heterocyclic compound and in consideration of a decrease in short-circuit current and in fill factor resulting from an increase in the viscosity of the heterocyclic compound.

Regarding the heterocyclic compound (A), the concentration thereof in the entire electrolytic solution is preferably 5 to 40% by volume and more preferably 10 to 30% by volume in further consideration of its low boiling point.

As stated above, Japanese Unexamined Patent Publication No. 2003-16849 discloses that tetrahydrofuran is contained in an electrolytic solution in a concentration of 50 to 99% by weight. When tetrahydrofuran, a highly volatile substance, is contained in such a concentration, a reduction in durability will occur in addition to the above problems of a decrease in the solubility of an imidazole salt and an increase in the viscosity of the heterocyclic compound. The present invention, in which the heterocyclic compound (A) is contained in the electrolytic solution in a concentration of 5 to 40% by volume, on the other hand, allows an increase in open-circuit voltage, a suppression of a decrease in short-circuit current and an increase in durability.

The electrolytic solution of the present invention may contain as conventionally a nitrogen-containing heterocyclic compound such as t-butyl pyridine (TBP) or the like; or an imidazole salt such as dimethyl propyl imidazole iodiode (DMPII), methyl propyl imidazole iodiode (MPII), ethyl methyl imidazole iodiode (EMII), ethyl imidazole iodiode (EII), hexyl methyl imidazole iodiode (HMII) or the like.

Also, the electrolytic solution may contain a compound having the same chemical species as that of a ligand of the metal complex dye.

### EXAMPLES

The invention will be described in more detail with reference to the following examples; however, the invention is not limited to the examples.

Heterocyclic Compound (A)

### Examples A-1 to A-8 and Comparative Examples 1 to 7

Using electrolytic solutions containing the heterocyclic compounds in Table 1 in the concentrations shown in the table, dye-sensitized solar cells were manufactured as follows.

TABLE 1

| No. | Heterocyclic compound | % By volume* |
|---|---|---|
| Example A-1 | Tetrahydrofuran | 10 |
| Example A-2 | Tetrahydrofuran | 40 |
| Example A-3 | 2-Methyl-tetrahydrofuran | 30 |
| Example A-4 | Pyran | 20 |
| Example A-5 | Pyran | 40 |
| Example A-6 | Tetrahydropyran | 20 |
| Example A-7 | Furan | 5 |
| Example A-8 | 2-Methyl-furan | 20 |
| Comp. Ex. 1 | Tetrahydrofuran | 70 |
| Comp. Ex. 2 | Pyran | 70 |
| Comp. Ex. 3 | Tetrahydropyran | 70 |
| Comp. Ex. 4 | 1,4-Dioxane | 90 |
| Comp. Ex. 5 | Trioxane | 90 |
| Comp. Ex. 6 | Furan | 70 |
| Comp. Ex. 7 | Not added | |

*Remainder is a mixture of acetonitrile, DMPII, lithium iodide, iodide and TBP.

Formation of a Porous Semiconductor Layer

First, a commercially available titanium oxide paste (trade name: Ti-Nanoxide D, average particle diameter: 13 nm, made by Solaronix Co., Swiss) was applied by a doctor blade method to a transparent conductive film of SnO₂ formed by vapor deposition on a transparent substrate of a glass plate (manufactured by Nippon Sheet Glass Co., Ltd., Japan). Next, the coated film was pre-heated at 300° C. for 30 minutes, and then calcined at 500° C. for 40 minutes to form a 20 μm-thick titanium oxide film as a porous semiconductor layer.

Adsorption of a Dye Sensitizer

First, a 4×10⁻⁴ mol/l solution of a dye sensitizer (trade name: Ruthenium 535-bisTBA dye, made by Solaronix Co., Swiss) in ethanol (made by Aldrich Chemical Company) was prepared. Next, the glass plate having the titanium oxide film formed thereon was immersed in the dye solution and kept submerged therein for 30 minutes so that the dye sensitizer was adsorbed in the titanium oxide film. The concentration of adsorbed dye sensitizer in the titanium oxide film was 7×10⁻⁸ mol/cm². After that, the glass plate was washed with ethanol (made by Aldrich Chemical Company) and dried.

Production of an Electrolytic Solution

The compounds in Table 1 (all made by Aldrich Chemical Company) were each dissolved in acetonitrile (made by Aldrich Chemical Company), and then in each of the resulting solutions, DMPII (made by Shikoku Kasei Corp., Japan), lithium iodide (made by Aldrich Chemical Company), iodide (made by Aldrich Chemical Company), and TBP (made by Aldrich Chemical Company) were all dissolved so that the concentrations of DMPII, lithium iodide, iodide and TBP were 0.6 mol/l, 0.1 mol/l 0.05 mol/l and 0.5 mol/l, respectively. Thus, redox electrolytic solutions each to be contained in a carrier transport layer were obtained.

Manufacturing of a Solar Cell

A 1 μm-thick platinum film as a counter electrode was formed by vapor deposition on the same transparent conductive glass plate as the one above that has the porous semiconductor layer formed thereon. The resulting transparent conductive glass plate was stacked on the other transparent conductive glass plate with a spacer inserted between the counter electrode and the porous semiconductor layer obtained above as a photoelectric conversion layer for preventing short-circuit. Then, the redox electrolytic solutions each were injected into the gap between the transparent conductive glass plates, and the side faces were sealed with an epoxy resin, followed by attaching lead wires to the respective electrodes. Thus, a solar cell was completed.

Light (AM 1.5 solar simulator) of an intensity of 1 kW/m² was applied to the solar cell obtained to evaluate the photoelectric conversion efficiency.

The results are shown in Table 2.

TABLE 2

| No. | Jsc (mA/cm²) | Voc (V) | FF | Effi. (%) |
|---|---|---|---|---|
| Example A-1 | 18.4 | 0.745 | 0.745 | 10.21 |
| Example A-2 | 18.3 | 0.760 | 0.720 | 10.01 |
| Example A-3 | 18.2 | 0.740 | 0.732 | 9.86 |
| Example A-4 | 17.9 | 0.751 | 0.722 | 9.71 |
| Example A-5 | 17.7 | 0.760 | 0.734 | 9.87 |
| Example A-6 | 17.7 | 0.742 | 0.746 | 9.80 |
| Example A-7 | 17.6 | 0.739 | 0.726 | 9.44 |
| Example A-8 | 17.5 | 0.754 | 0.722 | 9.53 |
| Comp. Ex. 1 | 16.9 | 0.766 | 0.690 | 8.93 |
| Comp. Ex. 2 | 16.8 | 0.771 | 0.701 | 9.08 |
| Comp. Ex. 3 | 16.7 | 0.772 | 0.689 | 8.88 |
| Comp. Ex. 4 | 15.9 | 0.744 | 0.642 | 7.59 |
| Comp. Ex. 5 | 16.1 | 0.778 | 0.722 | 9.04 |
| Comp. Ex. 6 | 15.8 | 0.742 | 0.700 | 8.20 |
| Comp. Ex. 7 | 16.5 | 0.730 | 0.688 | 8.29 |

Table 2 shows that the photoelectric conversion efficiency can be improved when a heterocyclic compound having an oxygen atom, in the ring thereof is contained in the electrolytic solution.

Heterocyclic Compound (B)

### Examples B-1 to B-10

Dye-sensitized solar cells were manufactured in the same manner as in Examples A-1 to A-8 except that the heterocyclic compounds in Table 3 were contained in the electrolytic solutions in the concentrations shown in the table.

TABLE 3

| No. | Heterocyclic compound | % By volume |
|---|---|---|
| Example B-1 | 4-Methyl-1,3-dioxolane | 20 |
| Example B-2 | 1,3-Dioxolane | 20 |
| Example B-3 | 1,3-Dioxane | 40 |
| Example B-4 | 1,4-Dixoane | 5 |
| Example B-5 | 1,4-Dixoane | 30 |
| Example B-6 | 2H-1,3-Dioxole | 60 |
| Example B-7 | 3H-1,2-Dioxole | 55 |
| Example B-8 | Dioxene | 70 |
| Example B-9 | 1,4-Dioxin | 20 |
| Example B-10 | Trioxane | 5 |
| Comp. Ex. 7 | Not added | |

The photoelectric conversion efficiencies of the dye-sensitized solar cells thus obtained were evaluated in the same manner as in Examples A-1 to A-8. The results are shown in Table 4.

TABLE 4

| No. | Jsc (mA/cm²) | Voc (V) | FF | Effi. (%) |
|---|---|---|---|---|
| Example B-1 | 16.5 | 0.755 | 0.710 | 8.84 |
| Example B-2 | 16.8 | 0.756 | 0.727 | 9.23 |
| Example B-3 | 17.9 | 0.755 | 0.709 | 9.58 |
| Example B-4 | 18.1 | 0.734 | 0.734 | 9.75 |
| Example B-5 | 17.8 | 0.766 | 0.721 | 9.83 |
| Example B-6 | 16.4 | 0.782 | 0.711 | 9.12 |
| Example B-7 | 16.5 | 0.779 | 0.712 | 9.15 |
| Example B-8 | 16.4 | 0.781 | 0.722 | 9.25 |
| Example B-9 | 16.3 | 0.788 | 0.737 | 9.47 |
| Example B-10 | 17.7 | 0.778 | 0.743 | 9.60 |
| Comp. Ex. 7 | 16.5 | 0.730 | 0.688 | 8.29 |

Table 4 shows that the photoelectric conversion efficiency can be improved when a heterocyclic compound having two oxygen atoms in the ring thereof is contained in the electrolytic solution.

Heterocyclic Compound (C)

### Examples C-1 to C-6

Dye-sensitized solar cells were manufactured in the same manner as in Examples A-1 to A-2 except that the heterocyclic compounds in Table 5 were contained in the electrolytic solutions in the concentrations shown in the table.

TABLE 5

| No. | Heterocyclic compound | % By volume |
|---|---|---|
| Example C-1 | Thiophene | 20 |
| Example C-2 | Thiophene | 40 |
| Example C-3 | Thiophene | 70 |
| Example C-4 | Tetrahydrothiophene | 20 |
| Example C-5 | Tetrahydrothiophene | 40 |
| Example C-6 | Tetrahydrothiophene | 80 |
| Comp. Ex. 7 | Not added | |

The photoelectric conversion efficiencies of the dye-sensitized solar cells thus obtained were evaluated in the same manner as in Examples A-1 to A-8. The results are shown in Table 6.

TABLE 6

| No. | Jsc (mA/cm²) | Voc (V) | FF | Effi. (%) |
|---|---|---|---|---|
| Example C-1 | 17.1 | 0.745 | 0.745 | 9.49 |
| Example C-2 | 16.8 | 0.760 | 0.720 | 9.20 |
| Example C-3 | 15.8 | 0.766 | 0.720 | 8.71 |
| Example C-4 | 17.3 | 0.751 | 0.722 | 9.38 |
| Example C-5 | 16.7 | 0.760 | 0.711 | 9.02 |
| Example C-6 | 16.5 | 0.767 | 0.710 | 8.99 |
| Comp. Ex. 7 | 16.5 | 0.730 | 0.688 | 8.29 |

Table 6 shows that the photoelectric conversion efficiency can be improved when a heterocyclic compound having at least one sulfur atom in the ring thereof is contained in the electrolytic solution.

According to the present invention, in which the heterocyclic compound having at least one oxygen atom and/or at least one sulfur atom in the ring thereof is contained in the electrolytic solution, a dye-sensitized solar cell with a high open-circuit voltage can be provided. The following is a conceivable reason why a high open-circuit voltage can be obtained: The oxygen atom and/or the sulfur atom in the compound are adsorbed on sites of the porous semiconductor layer and/or dye sensitizer from which sites electrons leak, so that the leakage of the electron (reverse current) can be suppressed.

1. A dye-sensitized solar cell comprising:
a transparent electrode;
a counter electrode;
a porous semiconductor layer having a dye sensitizer adsorbed therein; and
a carrier transport layer containing an electrolytic solution therein,
the porous semiconductor layer and the carrier transport layer being located between the transparent electrode and the counter electrode,
wherein the electrolytic solution contains a heterocyclic compound comprising a heteroatom in the ring.

2. A dye-sensitized solar cell comprising:
a transparent electrode;
a counter electrode;
a porous semiconductor layer having a dye sensitizer adsorbed therein; and
a carrier transport layer containing an electrolytic solution therein,
the porous semiconductor layer and the carrier transport layer being located between the transparent electrode and the counter electrode,
wherein the electrolytic solution contains a heterocyclic compound containing an oxygen atom in the ring, and the concentration of the heterocyclic compound in the electrolytic solution is 5 to 4-0% by volume.

3. A dye-sensitized solar cell of claim 2, wherein the heterocyclic compound is a compound having a five- or six-membered ring containing one oxygen atom in the ring.

4. A dye-sensitized solar cell of claim 2, wherein the heterocyclic compound is selected from the group consisting of furan, tetrahydrofuran, pyran and tetrahydropyran, each optionally substituted with a lower alkyl group.

5. A dye-sensitized solar cell comprising:
a transparent electrode;
a counter electrode;
a porous semiconductor layer having a dye sensitizer adsorbed therein; and
a carrier transport layer containing an electrolytic solution therein,
the porous semiconductor layer and the carrier transport layer being located between the transparent electrode and the counter electrode,
wherein the electrolytic solution contains a heterocyclic compound containing two or more oxygen atoms in the ring.

6. A dye-sensitized solar cell of claim 5, wherein the heterocyclic compound is a compound having a five- or six-membered ring.

7. A dye-sensitized solar cell of claim 5, wherein the heterocyclic compound has two or three heteroatoms in the ring thereof.

8. A dye-sensitized solar cell of claim 5, wherein the heterocyclic compound is selected from the group consisting of a compound having a five-membered ring containing two oxygen atoms in the ring, a compound having a six-membered ring containing two oxygen atoms in the ring, and a compound having a six-membered ring containing three oxygen atoms in the ring.

9. A dye-sensitized solar cell of claim 5, wherein the heterocyclic compound is selected from the group consisting of dioxolane, dioxane, dioxole, dioxene, dioxin and trioxane, each optionally substituted with a lower alkyl group.

10. A dye-sensitized solar cell of claim 5, wherein the concentration of the heterocyclic compound in the electrolytic solution is 5 to 80% by volume.

11. A dye-sensitized solar cell comprising:
a transparent electrode;
a counter electrode;
a porous semiconductor layer having a dye sensitizer adsorbed therein; and
a carrier transport layer containing an electrolytic solution therein,
the porous semiconductor layer and the carrier transport layer being located between the transparent electrode and the counter electrode,
wherein the electrolytic solution contains a heterocyclic compound containing at least one sulfur atom in the ring.

12. A dye-sensitized solar cell of claim 11, wherein the heterocyclic compound is a compound having a five- or six-membered ring.

13. A dye-sensitized solar cell of claim 11, wherein the heterocyclic compound is a compound having the ring containing one or two sulfur atoms in the ring.

14. A dye-sensitized solar cell of claim 11, wherein the heterocyclic compound is a compound having a five-membered ring containing one sulfur atom in the ring.

15. A dye-sensitized solar cell of claim 11, wherein the heterocyclic compound is selected from the group consisting of thiophene and tetrahydrothiophene, each optionally substituted with a lower alkyl group.

16. A dye-sensitized solar cell of claim 11, wherein the concentration of the heterocyclic compound in the electrolytic solution is 5 to 80% by volume.
